(19) United States
(12) Patent Application Publication
(10) Pub. No.: US 2024/0396289 A1
(43) Pub. Date: Nov. 28, 2024

(54) OPTOELECTRONIC LIGHTING DEVICE AND PRODUCTION METHOD

(71) Applicant: ams-OSRAM International GmbH, Regensburg (DE)

(72) Inventors: Andreas FROEHLICH, Regensburg (DE); Tobias GEBUHR, Bad Abbach (DE)

(73) Assignee: ams-OSRAM International GmbH, Regensburg (DE)

(21) Appl. No.: 18/684,544

(22) PCT Filed: Aug. 16, 2022
(86) PCT No.: PCT/EP2022/072882

§ 371 Date: Feb. 16, 2024

(30) Foreign Application Priority Data
Aug. 20, 2021 (DE) 10 2021 121 717.2

(51) Int. Cl. H01S 5/02218; H01S 5/0232; H01S 5/02345

(52) U.S. Cl. CPC H01S 5/02218; H01S 5/0232; H01S 5/02345

(57) ABSTRACT

The invention relates to an optoelectronic lighting device comprising a carrier, in particular a lead frame, at least one light emitting semiconductor element which is arranged on the carrier and is configured to emit pulsed light in a wavelength range, in particular in the infrared wavelength range, a first mold compound which is substantially transparent for the wavelength range and covers at least one light emitting region of the semiconductor element; and a second mold compound which is substantially transparent for the wavelength range and which is adjacent to the first mold compound when viewed in an emission direction of the semiconductor element. The first mold compound comprising a higher temperature resistance than the second mold compound.

### CROSS-REFERENCE TO RELATED APPLICATIONS

The present application is a national stage entry from International Application No. PCT/EP2022/072882, filed on Aug. 16, 2022, published as International Publication No. WO 2023/021048 A1 on Feb. 23, 2023, and claims priority to German patent application No. 10 2021 121 717.2 filed Aug. 20, 2021, the disclosures of all of which are hereby incorporated by reference in their entireties.

### FIELD

The present invention relates to an optoelectronic lighting device and to a method for manufacturing an optoelectronic lighting device.

### BACKGROUND

In the manufacture of QFN-based laser diodes, in particular side-emitting laser diodes, or laser diode arrays for use in LIDAR systems (light detection and ranging), for example, bonded and contacted diodes can currently be encapsulated with a clear silicone shell using a compression molding process. The clear silicone encapsulation is highly resistant to laser radiation and has good temperature resistance.

However, one problem is that the silicone has a certain stickiness on its surface compared to other, often organic, particles. This makes it more difficult, for example, to handle the components in the subsequent process, such as when they stick to a tool. In addition, there is a risk that tiny particles will stick to the silicone surface due to the stickiness, making it difficult to remove them. On the one hand, such particles can impair the beam quality of the light emitted by the component, and the particles can lead to undesirable heating in the area of the light emission window of the laser diode due to the light absorbed by them.

There is therefore a need to counteract at least one of the aforementioned problems and to specify an improved optoelectronic lighting device and a method for its manufacture.

### SUMMARY OF THE INVENTION

This and other needs are met by an optoelectronic lighting device with the features of claim 1 and a method for manufacturing an optoelectronic lighting device with the features of claim 15. Embodiments and further developments of the invention are described in the dependent claims.

An optoelectronic lighting device according to the invention comprises a carrier, in particular a lead frame, and at least one light emitting semiconductor element arranged on the carrier, in particular a laser diode, which is configured to emit pulsed light, in particular with a wavelength in the infrared wavelength range, for example with a peak wavelength at 850 nm, 905 nm or 940 nm. However, the laser diode can also be configured to emit light in the visible spectral range. A first mold compound, which is substantially transparent for the wavelength range, further covers at least one light emitting region of the semiconductor element, and a second mold compound, which is substantially transparent for the wavelength range, adjoins the first mold compound when viewed in an emission direction of the semiconductor element. The first mold compound in addition comprises a higher temperature resistance than the second mold compound.

By using two different mold compounds, i.e. double mold of the semiconductor element at least in the area of the light emitting region of the semiconductor element, the respective advantages of the two mold compounds can be combined to provide an improved optoelectronic lighting device. The first mold compound, which directly adjoins and covers the light emitting region of the semiconductor element, is characterized in particular by the fact that it has a higher temperature resistance than the second mold compound. This is particularly advantageous, since a material is arranged in the immediate vicinity of the light emitting region which is sufficiently temperature-stable with respect to the high optical power and the high energy density of the light emitted by the semiconductor element in the immediate vicinity of the light emitting region.

However, such a temperature-stable material can also have undesirable properties, such as a higher stickiness with respect to organic particles, for example, such as dust particles. The second mold compound, which, viewed in the emission direction of the semiconductor element, adjoins the first mold compound, in particular in the region of a light cone emitted by the semiconductor element, and in particular covers the first mold compound, can therefore be characterized in particular by the fact that it has a lower stickiness with respect to organic particles, for example. In particular, the second mold compound forms a light emission window through which the light emitted by the semiconductor element is radiated into the environment. By using the second mold compound in the area of the light emission window, the risk of, for example, organic particles adhering to the light emission window in the area of the light cone emitted by the semiconductor element can be reduced accordingly, so that the decoupling efficiency of the optoelectronic lighting device is reduced.

Since the energy density decreases with increasing distance from the semiconductor element due to the divergence of the light emitted by the semiconductor element as viewed in the emission direction of the semiconductor element, it is possible to use a less temperature-stable material for the second mold compound, but at the same time a less sticky material than that of the first mold compound, if the distance is sufficiently large. Advantageous properties of the first mold compound, such as higher temperature resistance, higher resistance to higher-energy light, and higher elasticity to compensate for stresses due to thermal expansion, can be combined accordingly with advantageous properties of the second mold compound, such as lower stickiness, especially of the outer surfaces of the second mold compound, lower sensitivity to particles, easier cleanability, and higher rigidity to provide a more stable outer surface.

In some embodiments, the first mold compound is arranged on the carrier and completely surrounds the semiconductor element. In particular, the first mold compound substantially surrounds all areas of the semiconductor element that are not in contact with the carrier. Accordingly, the semiconductor element is encapsulated on the carrier with the first mold compound.

In some embodiments, a third, in particular light-absorbing, mold compound covers the first and/or second mold compound at least partially outside a light cone emitted by the semiconductor element. Accordingly, the third mold compound covers areas of the first and/or second mold compound that are not located in the light emitting region in the direction of emission and thus do not lie in the light cone emitted by the semiconductor element. In particular, the third mold compound can cover or encapsulate the first and/or second mold compound in such a way that it substantially covers all areas of the first and/or second mold compound which are not located in the light cone emitted by the semiconductor element and which are not in contact with the carrier. The third mold compound can, for example, be formed by a black-colored epoxy or by an epoxy with lightabsorbing particles in it.

In some embodiments, the carrier is formed by a lead frame with a first contact region and a second contact region. The semiconductor element is arranged on the first contact region and electrically connected to it. Furthermore, the semiconductor element is electrically connected to the second contact region by means of a bonding wire. An optoelectronic lighting device designed in this way can, for example, be surface-mounted using SMT (surface-mounted technology).

In some embodiments, the bonding wire is completely encapsulated in the first mold compound. This can be particularly advantageous, as the bonding wire is thus protected from external influences and forces and tearing of the bonding wire can be prevented. In particular, this has the advantage over an embodiment in which the bonding wire is encapsulated in two different encapsulation compounds that any stresses or shear forces occurring between the different encapsulation compounds, in particular due to heating of the bonding wire and the semiconductor element, have no influence on the bonding wire.

In some embodiments, the first mold compound has at least one exposed first outer surface. The exposed first outer surface is in particular not covered by the second and/or the third mold compound, and is in particular arranged on a side facing away from the light emitting region of the semiconductor element. Due to such an arrangement, expansion of the first mold compound, for example due to heating of the semiconductor element, in the direction of the exposed first outer surface can take place without difficulty, and detachment of the semiconductor element or the first mold compound due to thermal stresses within the optoelectronic lighting device can be prevented. It is also conceivable that a cavity is provided between the first and the second and/or the third mold compound, which can serve as a buffer to allow expansion of the first mold compound, for example due to heating of the semiconductor element, in the direction of the cavity. This in turn can prevent detachment of the semiconductor element or the first mold compound due to thermal stresses within the optoelectronic lighting device.

In some embodiments, viewed in the direction of emission, a second outer surface of the first mold compound arranged downstream of the semiconductor element is arranged substantially perpendicularly on the carrier. Such an interface can result in particular from an injection molding or compression molding tool used for production. The vertical interface prevents refraction of the light emitted by the semiconductor element and the light propagates parallel to the substrate. The optoelectronic lighting device applied to a circuit board, for example, can thus be constructed in the form of an “optical bench” on the circuit board.

In some embodiments, a second outer surface of the first mold compound, which is arranged downstream of the semiconductor element in the direction of emission, is arranged substantially parallel to the light emitting region. Such an arrangement can, for example, improve the decoupling efficiency of the optoelectronic lighting device and reduce or avoid light refraction effects or reflections in the area of the second outer surface.

In some embodiments, a distance between the light emitting region and a second outer surface of the first mold compound downstream of the semiconductor element, as viewed in the direction of emission, is selected such that a power density of the light emitted by the semiconductor element in the region of the second outer surface does not exceed a defined threshold value. In particular, the threshold value is selected as a function of the temperature resistance of the second mold compound. The distance and thus the thickness of the first mold compound is selected in particular in such a way that the power density of the light emitted by the semiconductor element in the region of the second outer surface does not damage the second mold compound adjacent to the first mold compound or heats it beyond its temperature resistance due to the divergence of the light emitted by the semiconductor element. In other words, the threshold value is selected such that the power density of the light emitted by the semiconductor element in the region of the second outer surface causes no damage or no heating leading to damage in the second mold compound. The thickness of the first mold compound is thus selected in such a way that, due to the divergence of the light emitted by the semiconductor element, the power density of the light emitted by the semiconductor element in the region of the second outer surface is so low that the second mold compound adjacent to the first mold compound is not damaged or is heated beyond its temperature resistance.

In some embodiments, a distance between the light-emitting region and a second outer surface of the first encapsulant downstream of the semiconductor element, as viewed in the direction of emission, is selected to be between 10 μm and 100 μm inclusive. In contrast, a distance between the second outer surface of the first mold compound and an outer surface of the second mold compound downstream of the first mold compound, as viewed in the direction of emission, may be selected to be between 50 μm and 300 μm inclusive.

In particular, the outer surface of the second mold compound can lie in one plane with an outer surface of the carrier, and the two outer surfaces can together form an outer surface of the optoelectronic lighting device.

In some embodiments, viewed in the direction of emission, an outer surface of the carrier arranged downstream of the semiconductor element is arranged substantially parallel to the light emitting region. For this purpose, the semiconductor element can be arranged on the carrier in such a way that the light emitting region is arranged substantially parallel to an outer surface of the carrier downstream of the semiconductor element. A distance, in particular the normal distance, between the outer surface of the carrier and the light emitting region can be selected in such a way that the light cone emitted by the semiconductor element does not overlap with the carrier. The light cone emitted by the semiconductor element therefore does not impinge on the carrier and is therefore not deflected or absorbed in the area of impingement. Such a phenomenon is also known as “beam clipping” and should be prevented as far as possible.

In some embodiments, the first mold compound is selected from the group of silicones. In particular, the first mold compound may be characterized, for example, by a high temperature resistance, a high resistance to high-energy light, and by elastic properties to compensate for stresses due to thermal expansion.

In some embodiments, the second mold compound is selected from the group of epoxies or from the group of glasses. In particular, the second mold compound may be characterized, for example, by low stickiness, in particular of outer surfaces of the second mold compound, low sensitivity to particles, easy cleanability, and high rigidity to provide a stable outer surface.

In some embodiments, outer surfaces of the first mold compound have a higher tack than outer surfaces of the second mold compound. On the one hand, this can contribute to improved adhesion between the first and the second mold compound and, in addition, has the advantage that a component surface of the optoelectronic lighting device made of the second mold compound is less sticky than a component surface of the optoelectronic lighting device made of the first mold compound. This results in easier handling during possible further processing of the optoelectronic lighting device, for example by means of a pick & place process, better resistance to particles and better cleanability of the optoelectronic lighting device.

Such an optoelectronic lighting device can be particularly suitable for use in LIDAR systems (light detection and ranging).

A method of manufacturing an optoelectronic lighting device according to some aspects of the proposed principle comprises the steps of:

Arranging a light emitting semiconductor element, in particular a laser diode, which is configured to emit pulsed light in a wavelength range, in particular infrared wavelength range, for example with a peak wavelength at 850 nm, 905 nm or 940 nm, on a carrier, in particular a lead frame;
electrically contacting the semiconductor element and the carrier;
compression molding or injection molding a first mold compound which is substantially transparent for the wavelength range onto the semiconductor device and/or the carrier in such a way that at least one light emitting region of the semiconductor element is covered; and
applying a second mold compound that is substantially transparent for the wavelength range in such a way that the second mold compound is at least adjacent to the first mold compound when viewed in an emission direction of the semiconductor element;
wherein the first mold compound comprises a higher temperature resistance than the second mold compound.

In some embodiments, the method further comprises compression molding or injection molding a light-absorbing third mold compound onto the first and/or second mold compound and/or the carrier such that regions downstream of the light emitting region in the emission direction remain free of the third mold compound.

In some embodiments, after the step of compression molding or injection molding the first mold compound, the first mold compound is cured.

In some embodiments, the step of applying the second mold compound comprises compression molding or injection molding.

In some embodiments, the step of applying the second mold compound comprises disposing a preformed laser bevel comprising the second mold compound.

In some embodiments, the step of electrically contacting the semiconductor element comprises wire bonding.

In some embodiments, the step of applying the second mold compound and/or the step of compression molding or injection molding of the third mold compound is carried out in such a way that an area of the first mold compound facing away from the emission area remains free.

An optoelectronic lighting device manufactured in this way can be particularly suitable for use in LIDAR systems (light detection and ranging).

### BRIEF DESCRIPTION OF THE DRAWINGS

In the following, embodiments of the invention are explained in more detail with reference to the accompanying drawings. They show, in each case schematically,

FIG. 1 a sectional view of an embodiment of an optoelectronic lighting device according to some aspects of the proposed principle;

FIG. 2 a sectional view of a further embodiment of an optoelectronic lighting device according to some aspects of the proposed principle;

FIG. 3 a sectional view of a further embodiment of an optoelectronic lighting device according to some aspects of the proposed principle; and

FIG. 4 a sectional view of a further embodiment of an optoelectronic lighting device according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

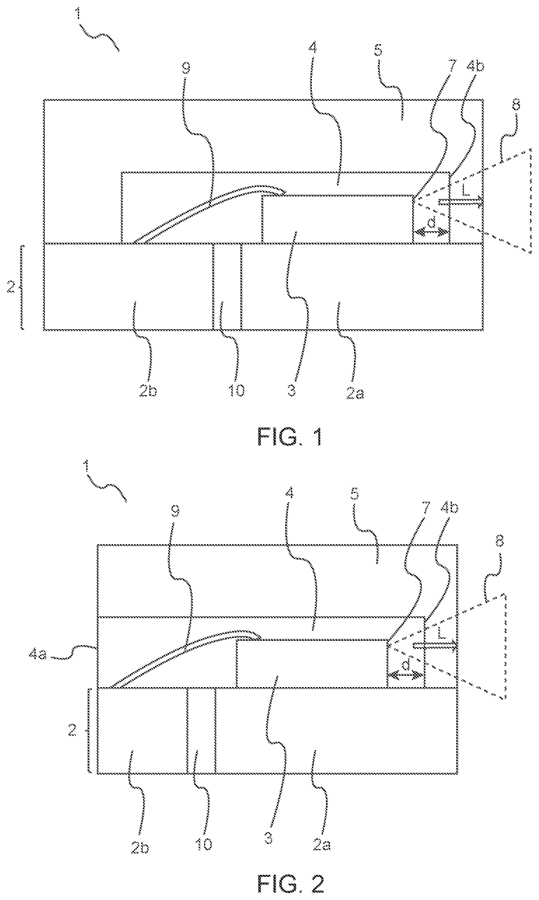

FIG. 1 shows a sectional view of a first embodiment of an optoelectronic lighting device 1 according to some aspects of the proposed principle. The optoelectronic lighting device 1 comprises a lead frame 2, which has a first contact region 2a and a second contact region 2b. The two contact areas 2a, 2b are mechanically connected to each other by an insulating material 10.

A semiconductor element 3 in the form of a laser diode is arranged on the first contact region 2a and electrically connected to it. The laser diode is also electrically connected to the second contact region 2b by means of a bonding wire 9. The laser diode 3 is configured in particular to emit pulsed light in a wavelength range, in particular in the infrared wavelength range, for example with a peak wavelength at 850 nm, 905 nm or 940 nm. In particular, the laser diode is designed in the form of a side-emitting emitter and has a light emitting region 7 on one of the lateral outer surfaces of the laser diode 3, through which the laser diode 3 emits light in the form of a light cone 8 in the direction of an emission direction L.

The laser diode 3 is encapsulated on the carrier 2 by means of a first mold compound 4, so that the laser diode 3 and the bonding wire 9 are completely enclosed by the first mold compound 4. In this context, in combination with the illustration in FIG. 1, completely enclosed means that areas in which the laser diode 3 and the bonding wire 9 are not in contact with the carrier 2 are enclosed by the first mold compound 4. In particular, at least the light emitting region 7 of the semiconductor element 3 is covered by the first mold compound 4.

In addition, the optoelectronic lighting device 1 comprises a second mold compound 5, which in turn encapsulates the first mold compound 4 or the laser diode 3 encapsulated therein on the carrier 2. The second mold compound 5 completely encloses the first mold compound 4 according to the illustrated embodiment example. In this context, in combination with the illustration in FIG. 1, completely enclosed means that areas in which the first mold compound 4 is not in contact with the carrier, the laser diode 3 and the bonding wire 9 are enclosed by the second mold compound 5. In particular, at least the area of the first mold compound 4 that lies within the light cone 8 is covered by the second mold compound 5.

Seen in the direction of emission L, the first mold compound 4 has an outer surface 4b downstream of the laser diode 3, which is arranged substantially perpendicular to the carrier 3 and substantially parallel to the light emitting region 7. Such an interface can result in particular from an injection molding or compression molding tool used for production.

A distance d between the light emitting region 7 and the outer surface 4b is selected in such a way that a power density of the light emitted by the laser diode 3 in the area of the outer surface 4b does not exceed a defined threshold value. The threshold value is selected as a function of the temperature resistance of the second mold compound 5 in such a way that the power density of the light emitted by the laser diode 3 in the area of the outer surface 4b does not damage the second mold compound 5 adjacent to the first mold compound 4 or heat it beyond its temperature resistance due to the divergence of the light emitted by the laser diode 3. The distance d between the light emitting region 7 and the outer surface 4b is thus selected in such a way that the power density of the light that impinges on the second mold compound 5 does not damage the second mold compound 5 or heat it beyond its temperature resistance due to the widening of the light cone 8 emitted by the laser diode 3 and thus a reduction in the power density.

This is particularly advantageous, since a material (first mold compound 4) is arranged in the immediate vicinity of the light emitting region 7, which is sufficiently temperature-stable with respect to the high optical power and the high energy density of the light emitted by the laser diode 3 in the immediate vicinity of the light emitting region. The second mold compound 5, on the other hand, is arranged at a distance d from the light emitting region 7 in which the power density of the light that impinges on the second mold compound 5 is reduced in such a way that the second mold compound 5 is not damaged or is heated beyond its temperature resistance.

Furthermore, the lateral outer surface of the second mold compound 5 lies in one plane with the lateral outer surface of the carrier 2. The lateral outer surfaces of the second mold compound 5 and the carrier 2 together form the lateral outer surfaces of the optoelectronic lighting device 1.

The laser diode 3 is arranged on the carrier 2 in such a way that the light emitting region 7 is arranged substantially parallel to a lateral outer surface of the carrier 2. The normal distance between the outer surface of the carrier 2 and the light emitting region 7 is selected in such a way that the light cone 8 emitted by the laser diode 3 does not overlap with the carrier 2. The light cone 8 emitted by the laser diode 3 therefore does not impinge on the carrier 2 and is therefore not deflected or absorbed by the carrier 2 in the area of impingement. Beam clipping is therefore prevented.

FIG. 2 shows a sectional view of a further embodiment example of an optoelectronic lighting device according to some aspects of the proposed principle. The embodiment example substantially corresponds to the embodiment example shown in FIG. 1, with the difference that the first mold compound 4 has an exposed first outer surface 4a which is not covered by the second mold compound 5. The first outer surface 4a is arranged on a side facing away from the light emitting region 7 of the laser diode 3 and, together with a lateral outer surface of the second mold compound 5 and the carrier 2, forms a lateral outer surface of the optoelectronic lighting device 1.

Due to such an arrangement, expansion of the first mold compound, for example due to heating of the laser diode 3, in the direction of the exposed first outer surface 4a can take place without difficulty, and detachment of the laser diode 3 or the first mold compound 4 due to thermal stresses within the optoelectronic lighting device 1 can be prevented.

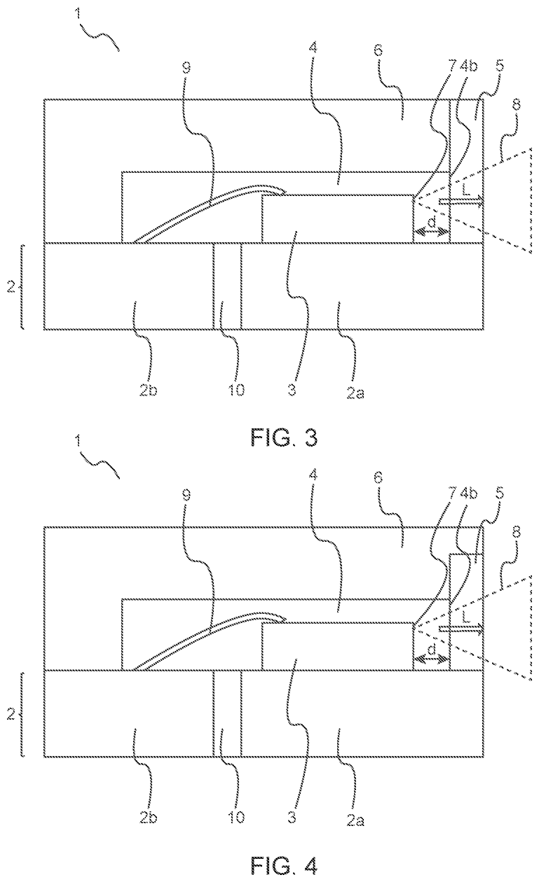

FIGS. 2 and 3 show two further embodiments of an optoelectronic lighting device according to some aspects of the proposed principle, each in a sectional view. The two embodiments substantially correspond to the embodiment shown in FIG. 1, with the difference that the second encapsulation compound 5 is substantially limited to an area in the direction of which light emission of the optoelectronic lighting device 1 is desired, or which lies within the light cone 8.

The second mold compound 5 is only adjacent to the outer surface 4b of the first mold compound 4 and does not completely encapsulate it. Instead, the optoelectronic lighting device 1 has a third light-absorbing mold compound 6, which at least partially encapsulates the remaining areas of the first mold compound 4 and, as shown in FIG. 4, the second mold compound 5.

The light-absorbing third mold compound 6 ensures that light is only coupled out of the optoelectronic lighting device 1 in the direction of emission L.

The second mold compound 5 can be applied to the carrier 2 by a separate injection compression or injection molding process, or can be applied to the carrier 2 in the form of a preformed laser facet comprising the second mold compound 5.

As shown in FIG. 3, a lateral outer surface of the second mold compound 5 together with a lateral outer surface of the carrier 2 can form an entire lateral outer surface of the optoelectronic lighting device 1, or the second mold compound 5 can be limited only to the area of the light cone 8 and can be arranged downstream of the first mold compound 4 only within the light cone 8, so that a lateral outer surface of the optoelectronic lighting device 1 also comprises a lateral outer surface of the third mold compound 6.

The invention claimed is:

1. An optoelectronic lighting device comprising:
a carrier, in particular a lead frame;
at least one light emitting semiconductor element arranged on the carrier, which is configured to emit pulsed light in a wavelength range, in particular in the infrared wavelength range;
a first mold compound which is substantially transparent for the wavelength range and covers at least one light emitting region of the semiconductor element; and
a second mold compound which is substantially transparent for the wavelength range and which is adjacent to the first mold compound when viewed in an emission direction of the semiconductor element;
wherein the first mold compound has a higher temperature resistance than the second mold compound, and
wherein the second mold compound is selected from the group of epoxides or from the group of glasses, and
wherein, when viewed in the emission direction, a second outer surface of the first mold compound arranged downstream of the semiconductor element is arranged substantially vertically on the carrier.

2. The optoelectronic lighting device according to claim 1,
wherein the first mold compound is arranged on the carrier and completely encloses the semiconductor element.

3. The optoelectronic lighting device according to claim 1,
wherein a third light-absorbing mold compound covers the first and/or second mold compound at least partially outside a light cone emitted by the semiconductor element.

4. The optoelectronic lighting device according to claim 1,
wherein the carrier is formed by a lead frame with a first contact region and a second contact region, wherein the semiconductor element is arranged on the first contact region and is electrically connected thereto, and wherein the semiconductor element is electrically connected to the second contact region by means of a bonding wire.

5. The optoelectronic lighting device according to claim 4,
wherein the bonding wire is completely molded in the first mold compound.

6. The optoelectronic lighting device according to claim 1,
wherein the first mold compound comprises at least one exposed first outer surface, which in particular is not covered by the second mold compound, and which is arranged on a side facing away from the light emitting region of the semiconductor element.

7. (canceled)

8. The optoelectronic lighting device according to claim 1,
wherein, when viewed in the emission direction, a second outer surface of the first mold compound arranged downstream of the semiconductor element is arranged substantially parallel to the light emitting region.

9. The optoelectronic lighting device according to claim 1,
wherein a distance (d) between the light emitting region and a second outer surface of the first mold compound, when viewed in the emission direction, downstream of the semiconductor element is selected such that a power density of the light emitted by the semiconductor element in the region of the second outer surface does not exceed a defined threshold value.

10. The optoelectronic lighting device according to claim 9,
wherein the threshold value is selected depending on the temperature resistance of the second mold compound.

11. The optoelectronic lighting device according to claim 1,
wherein a distance between the light emitting region and a second outer surface of the first mold compound downstream of the semiconductor element, when viewed in the emission direction, is selected to be between 10 μm and 100 μm inclusive.

12. The optoelectronic lighting device according to claim 1,
wherein the first mold compound is selected from the group of silicones.

13. The optoelectronic lighting device according to claim 1,
wherein outer surfaces of the first mold compound have a higher stickiness than outer surfaces of the second mold compound.

14. A method for manufacturing an optoelectronic lighting device comprising:
arranging a light emitting semiconductor element, which is configured to emit pulsed light in a wavelength range, in particular in the infrared wavelength range, on a carrier, in particular a lead frame;
electrical contacting the semiconductor element with the carrier;
compression molding or injection molding a first mold compound which is substantially transparent for the wavelength range onto the semiconductor element and/or the carrier in such a way that at least one light emitting region of the semiconductor element is covered; and
applying a second mold compound which is substantially transparent for the wavelength range in such a way that the second mold compound is at least adjacent to the first mold compound when viewed in an emission direction of the semiconductor element;
wherein the first mold compound comprises a higher temperature resistance than the second mold compound, and
wherein the second mold compound is selected from the group of epoxides or from the group of glasses,
wherein, when viewed in the emission direction, a second outer surface of the first mold compound arranged downstream of the semiconductor element is arranged substantially vertically on the carrier.

15. The method according to claim 14,
further comprising a step of compression molding or injection molding of a lightabsorbing third mold compound onto the first and/or second mold compound and/or the carrier in such a way that regions which are downstream of the light emitting region in the emission direction remain free of the third mold compound.

16. The method according to claim 14,
wherein after the step of compression molding or injection molding the first mold compound, the first mold compound is cured.

17. The method according claim 14,
wherein the step of applying the second mold compound comprises compression molding or injection molding.

18. The method according claim 14,
wherein the step of applying the second mold compound comprises arranging a preformed laser bevel comprising the second mold compound.

19. The method according claim 14,
wherein the step of electrically contacting the semiconductor element comprises wire bonding.

20. The method according claim 14,
wherein the step of applying the second mold compound and/or the step of compression molding or injection molding the third mold compound is carried out in such a way that a region of the first mold compound facing away from the emission region remains free.
